(19) United States
(12) Patent Application Publication
(10) Pub. No.: US 2024/0204767 A1
(43) Pub. Date: Jun. 20, 2024

(54) SEMICONDUCTOR INTEGRATED CIRCUIT

(71) Applicant: Kosuke Yamamoto, Tokyo (JP)

(72) Inventor: Kosuke Yamamoto, Tokyo (JP)

(73) Assignee: MITSUMI ELECTRIC CO., LTD., Tokyo (JP)

(21) Appl. No.: 18/529,033

(22) Filed: Dec. 5, 2023

(30) Foreign Application Priority Data
Dec. 16, 2022 (JP) 2022-201515

(51) Int. Cl. H03K 17/082; H01L 23/62; H02H 3/08

(52) U.S. Cl. CPC H03K 17/0822; H01L 23/62; H02H 3/08

(57) ABSTRACT

A semiconductor integrated circuit includes a drive terminal, first and second sense terminals, a current source that generates a drive current to be supplied to the drive terminal, an amplifier circuit that differentially amplifies a sense voltage between the first and second sense terminals, and outputs an analog differential voltage, an analog-to-digital converter that converts the analog differential voltage output from the amplifier circuit into a digital value, a command circuit that generates a command signal based on the digital value, so that the sense voltage does not deviate outside a predetermined range, an overcurrent detection circuit that asserts a detection signal when the sense voltage exceeds a predetermined voltage, and a logic circuit that generates a drive pattern for causing the current source to generate the drive current according to the command signal, and stops the supply of the drive current when the detection signal is asserted.

### CROSS-REFERENCE TO RELATED APPLICATIONS

This application is based upon and claims priority to Japanese Patent Application No. 2022-201515, filed on Dec. 16, 2022, the entire contents of which are incorporated herein by reference.

### TECHNICAL FIELD

The present disclosure relates to semiconductor integrated circuits.

### BACKGROUND

Conventionally, there is a known motor control circuit including a drive stage for driving a semiconductor switch element, and an overcurrent protection circuit for making the drive stage inactive when a voltage generated by a resistor connected in series to the semiconductor switch element exceeds a limit value. An example of such a motor control circuit is proposed in U.S. Patent Application Publication No. US 2012/0319632 A1, for example.

However, although the motor control circuit described above can protect a driving target connected to a drive terminal from the overcurrent, it is difficult to limit an operating current flowing through the driving target to a desired value.

### SUMMARY

One aspect of the embodiments of the present disclosure provides a semiconductor integrated circuit having a current limiting function and an overcurrent protection function.

According to a first aspect of the present disclosure, a semiconductor integrated circuit includes a drive terminal; a first sense terminal; a second sense terminal; a current source configured to generate a drive current to be supplied to the drive terminal; an amplifier circuit configured to differentially amplify a sense voltage between the first sense terminal and the second sense terminal, and output an analog differential voltage; an analog-to-digital converter configured to convert the analog differential voltage output from the amplifier circuit into a digital value; a command circuit configured to generate a command signal based on the digital value, so that the sense voltage does not deviate outside a predetermined range; an overcurrent detection circuit configured to assert a detection signal when the sense voltage exceeds a predetermined voltage; and a logic circuit configured to generate a drive pattern for causing the current source to generate the drive current according to the command signal, and stop the supply of the drive current when the detection signal is asserted.

According to a second aspect of the present disclosure, a semiconductor integrated circuit includes a drive terminal; a first sense terminal; a second sense terminal; a current source configured to generate a drive current to be supplied to the drive terminal; an amplifier circuit configured to differentially amplify a sense voltage between the first sense terminal and the second sense terminal, and output an analog differential voltage; an analog-to-digital converter configured to convert the analog differential voltage output from the amplifier circuit into a digital value; a command circuit configured to vary a command signal according to a variation in the digital value, and stop varying the command signal when the digital value reaches a limit value; an overcurrent detection circuit configured to assert a detection signal when the sense voltage exceeds a predetermined voltage; and a logic circuit configured to generate a drive pattern for causing the current source to generate the drive current according to the command signal, and stop the supply of the drive current when the detection signal is asserted.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a diagram illustrating an example of a configuration of a semiconductor integrated circuit according to one embodiment;

FIG. 2 is a diagram illustrating an example of a configuration of an amplifier circuit and an overcurrent detection circuit;

FIG. 3 is a characteristic diagram illustrating an example of a relationship between an operating current Io and sense voltages VRSM and VRSP;

FIG. 4 is a characteristic diagram illustrating an example of a relationship between the operating current Io and amplified output voltages VOUTM and VOUTP;

FIG. 5 is a characteristic diagram illustrating an example of a relationship of the operating current Io, a single end signal VCOMP, and a threshold voltage Vth;

FIG. 6 is a diagram illustrating an example of a configuration example of a power conversion device including the semiconductor integrated circuit according to one embodiment; and

FIG. 7 is a diagram illustrating an example of a pulse width modulation signal and a drive pattern.

### DETAILED DESCRIPTION

A description will hereinafter be given of embodiments of the present invention with reference to the drawings.

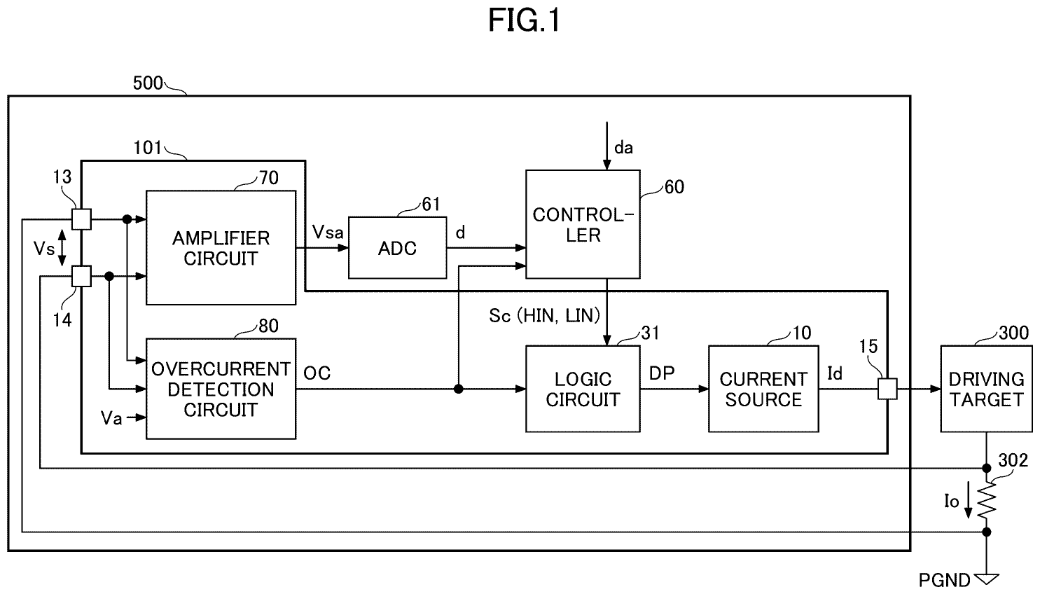

FIG. 1 is a diagram illustrating an example of a configuration of a semiconductor integrated circuit according to one embodiment. A semiconductor integrated circuit 500 is configured to feed back a detection result of an operating current Io of the driving target 300, and to drive the driving target 300 according to the feedback result. The semiconductor integrated circuit 500 includes a drive circuit 101, an analog-to-digital converter (ADC) 61, and a controller 60.

The drive circuit 101 is a pre-driver configured to drive the driving target 300 according to a pulse width modulation signal Sc supplied from the controller 60. The drive circuit 101 includes a current source 10, a drive terminal 15, a first sense terminal 13, a second sense terminal 14, an amplifier circuit 70, an overcurrent detection circuit 80, and a logic circuit 31.

The current source 10 is a circuit configured to generate a drive current Id to be supplied to the drive terminal 15 to which the driving target 300 is electrically connected. The current source 10 is configured to supply the drive current Id to the drive terminal 15 according to a drive pattern DP generated by the logic circuit 31.

The drive current Id generated by the current source 10 is supplied to the drive terminal 15. The drive current Id for driving the driving target 300 is supplied to the drive terminal 15, to thereby operate the driving target 300. The operating current Io of the driving target 300 flows when the driving target 300 is operated. The operating current Io of the driving target 300 flows to a sense resistor 302 that is connected in series to the driving target 300. The sense resistor 302 is an element inserted in series in a current path between the driving target 300 and a power ground PGND.

The first sense terminal 13 is a monitor terminal that is electrically connected to a first resistor end of the sense resistor 302 on the side of the power ground PGND, and is configured to monitor a potential of the first resistor end. The second sense terminal 14 is a monitor terminal that is electrically connected to a second resistor end of the sense resistor 302, opposite to the first resistor end, and is configured to monitor a potential of the second resistor end.

The amplifier circuit 70 is a differential amplifier circuit configured to differentially amplify a sense voltage Vs, which is a potential difference between the first sense terminal 13 and the second sense terminal 14, and to output a differentially amplified analog voltage (or an analog differential voltage Vsa). A magnitude of the sense voltage Vs represents a magnitude of the operating current Io. A polarity of the sense voltage Vs represents a direction of the operating current Io. For example, a positive sense voltage Vs represents a positive operating current Io, and a negative sense voltage Vs represents a negative operating current Io, which is a current in an opposite direction to the positive operating current Io.

The ADC 61 is a converter configured to convert the analog differential voltage Vsa output from the amplifier circuit 70 into a digital value d representing the magnitude and the direction of the operating current Io.

The controller 60 has a pulse width modulation function for generating the pulse width modulation signal Sc, based on the digital value d output from the ADC 61. The controller 60 is an example of a command circuit. The pulse width modulation signal Sc is an example of a command signal generated by performing a predetermined computation process based on the digital value d.

For example, in a case where the value of the operating current Io is adjusted to a predetermined target current value, the controller 60 generates the pulse width modulation signal Sc so that the digital value d converges to a target value da corresponding to the target current value.

Alternatively, in a case where the driving target 300 is an inverter as will be described later and is configured to generate an alternating current to be supplied to a motor, the operating current Io may be a current flowing through the inverter. In this case, the controller 60 generates the pulse width modulation signal Sc for driving a switching circuit of each phase in the inverter, based on a motor rotation speed command supplied from an external device (not illustrated) and the digital value d output from the ADC 61, for example.

In the present embodiment, the controller 60 generates the pulse width modulation signal Sc, based on the digital value d output from the ADC 61, so that the sense voltage Vs does not deviate outside a predetermined range (hereinafter, also referred to as a “sense voltage range A”). In this case, it is possible to obtain a current limiting function that limits a variation in the operating current Io so that as not to deviate outside a current range (hereinafter, also referred to as a “current limiting range B”) corresponding to the sense voltage range A. Further, it is possible to obtain a current limiting function that limits the variation in the operating current Io so that the operating current Io does not cross a current limit value that is an upper limit or a lower limit of the current limiting range B.

In the present embodiment, the controller 60 may vary the duty ratio of the pulse width modulation signal Sc according to a variation in the digital value d, and stop varying the duty ratio of the pulse width modulation signal Sc when the digital value d reaches a limit value (hereinafter, also referred to as a “limit value db”). In this case, it is possible to obtain a current limiting function that limits the variation in the operating current Io, so that the operating current Io does not cross the current limit value corresponding to the limit value db. In a state where the digital value d reached the limit value db, the controller 60 may output the pulse width modulation signal Sc so that the duty ratio becomes constant. In this case, it is possible to obtain a current limiting function that maintains the value of the operating current Io at the current limit value.

The functions of the controller 60 may be implemented in a processor, such as a central processing unit (CPU) or the like, that performs a processing operation by executing a program stored in a memory. Functions of the controller 60 may be implemented in a field programmable gate array (FPGA) or an application specific integrated circuit (ASIC).

The overcurrent detection circuit 80 is configured to monitor whether or not the sense voltage Vs exceeds a predetermined voltage Va. When the overcurrent detection circuit 80 detects the sense voltage Vs exceeding the predetermined voltage Va, the overcurrent detection circuit 80 asserts a detection signal OC. The detection signal OC is also referred to as an overcurrent detection signal. The assertion of the detection signal OC indicates that the overcurrent detection circuit 80 detected the sense voltage Vs exceeding the predetermined voltage Va (in other words, that an excessively large operating current Io is flowing). For example, in a case where the detection signal OC is a high active signal, the overcurrent detection circuit 80 asserts the detection signal OC by switching a level of the detection signal OC to a high level. The detection signal OC is supplied to at least one of the logic circuit 31 and the controller 60.

The logic circuit 31 is configured to generate the drive pattern DP for causing the current source 10 to generate the drive current Id according to the pulse width modulation signal Sc. The drive pattern DP defines a timing at which the current source 10 supplies the drive current Id to the drive terminal 15. The current source 10 causes the drive current Id to be supplied to the drive terminal 15 according to the drive pattern DP, so that the driving target 300 operates in a mode corresponding to the pulse width modulation signal Sc, and the operating current Io flows.

On the other hand, the logic circuit 31 is configured to stop the supply of the drive current Id to the drive terminal 15 when the assertion of the detection signal OC is detected by the controller 60 or the logic circuit 31 (that is, when the detection signal OC having the active level is detected). The logic circuit 31 may stop the supply of the drive current Id by stopping the generation of the drive pattern DP, or may stop the supply of the drive current Id by stopping the operation of the current source 10 by cutting off power to the current source 10 or the like. Alternatively, a low dropout regulator (LDO) that generates a power supply voltage of the controller 60 may drop the power supply voltage of the controller 60 when the assertion of the detection signal OC is detected. When the power supply voltage of the controller 60 drops, the output of the pulse width modulation signal Sc from the controller 60 stops, and thus the output of the drive pattern DP from the logic circuit 31 also stops, and thus, the supply of the drive current Id is stopped by the logic circuit 31. The method of stopping the supply of the drive current Id when the assertion of the detection signal OC is detected is not limited to the methods described above.

When the supply of the drive current Id stops, the operation of the driving target 300 stops, and thus, the flow of the operating current Io of the driving target 300 also stops. Accordingly, it is possible to prevent an excessively large operating current Io from flowing to the driving target 300.

As described above, according to the present embodiment, it is possible to provide the semiconductor integrated circuit 500 having both the current limiting function that limits the value of the operating current Io to the current limit value, and the overcurrent protection function that protects the driving target 300 from the overcurrent. In addition, because the amplifier circuit 70 and the overcurrent detection circuit 80 acquire the sense voltage Vs from the common sense terminals 13 and 14, the number of sense terminals can be reduced, and a scale or size of the semiconductor integrated circuit 500 can be reduced.

Next, an example of a configuration of the amplifier circuit and the overcurrent detection circuit will be described.

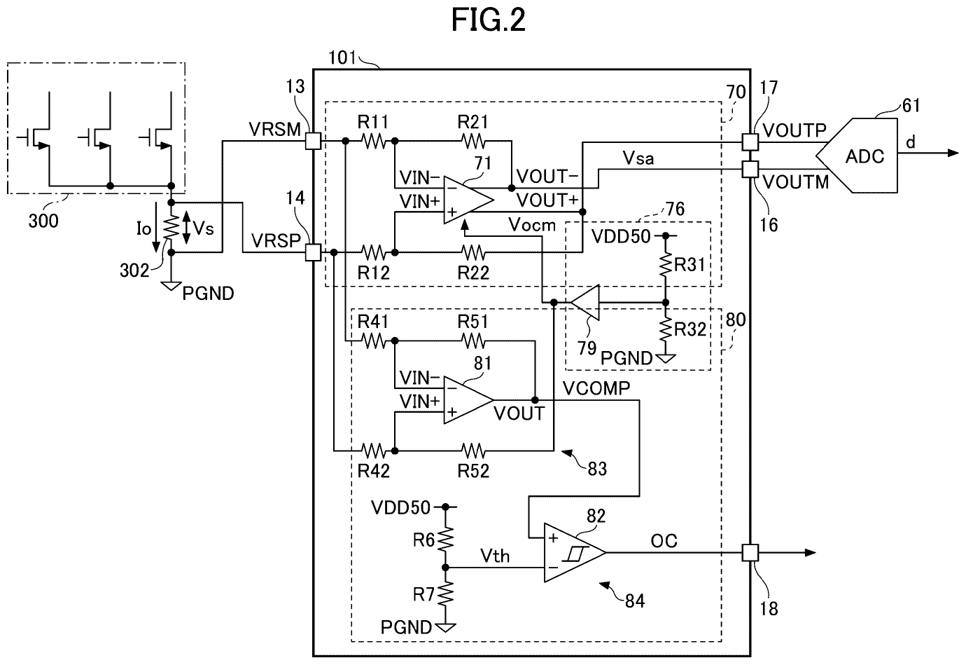

FIG. 2 is a diagram illustrating the example of the configuration of the amplifier circuit and the overcurrent detection circuit. The drive circuit 101 illustrated in FIG. 2 includes the amplifier circuit 70, the overcurrent detection circuit 80, a setting circuit 76, the first sense terminal 13, the second sense terminal 14, a first amplification output terminal 16, a second amplification output terminal 17, and a detection output terminal 18.

The amplifier circuit 70 differentially amplifies the sense voltage Vs input between the first sense terminal 13 and the second sense terminal 14, and outputs the analog differential voltage Vsa which is a product of the sense voltage Vs and a gain. The amplifier circuit 70 includes a differential input and differential output circuit including a differential amplifier 71, and a plurality of resistors R11, R21, R12, and R22. The differential amplifier 71 includes a first input terminal VIN−, a second input terminal VIN+, a first output terminal VOUT−, a second output terminal VOUT+, and a setting terminal VOCM. The analog differential voltage Vsa corresponds to a difference (=(Vout+)−(Vout−)) between a first output voltage Vout− of the first output terminal VOUT− and a second output voltage Vout+ of the second output terminal VOUT+.

The resistor R11 is connected between the first sense terminal 13 and the first input terminal VIN−. The resistor R12 is connected between the second sense terminal 14 and the second input terminal VIN+. The resistor R21 is connected between the first output terminal VOUT− and the first input terminal VIN−. The resistor R22 is connected between the second output terminal VOUT+ and the second input terminal VIN+. The first output terminal VOUT− is connected to the first amplification output terminal 16. The second output terminal VOUT+ is connected to the second amplification output terminal 17. For example, the resistor R11 and the resistor R12 are set to have the same resistance value R11, and the resistor R21 and the resistor R22 are set to have the same resistance value R21, so that the gain of the amplifier circuit 70 is (R21/R11).

The setting circuit 76 generates a common mode setting voltage Vocm to be input to the setting terminal Vocm of the differential amplifier 71. In this example, the setting circuit 76 outputs a voltage, obtained by dividing a power supply voltage VDD50 by resistors R31 and R32 forming a resistance voltage divider, as the common mode setting voltage Vocm from a buffer 79. The resistor R31 and R32 have the same resistance value, or may have different resistance values.

The differential amplifier 71 includes an internal circuit that controls the common mode voltage Voc (=((Vout+)+(Vout−))/2), which is an average of the first output voltage Vout− and the second output voltage Vout+ forming the analog differential voltage Vsa, to the common mode setting voltage Vocm. The common mode setting voltage Vocm enables the semiconductor integrated circuit 500 to cope with a negative operating current Io.

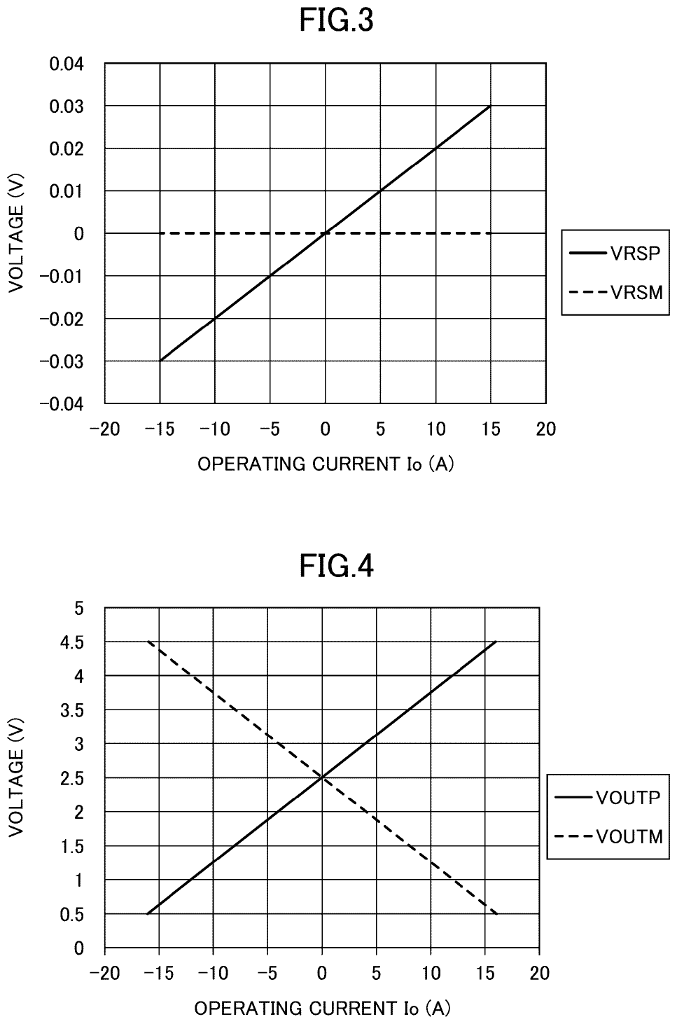

FIG. 3 is a characteristic diagram illustrating an example of a relationship between the operating current Io and sense voltages VRSM and VRSP. Because the first sense terminal 13 is connected to the power ground PGND, the sense voltage VRSM of the first sense terminal 13 is approximately zero regardless of the value of the operating current Io. The sense voltage VRSP of the second sense terminal 14 increases proportionally to an increase in the operating current Io. The sense voltage Vs corresponds to a difference (=VRSP−VRSM) between the sense voltage VRSP and the sense voltage VRSM. Accordingly, the sense voltage Vs increases proportionally to the increase in the operating current Io.

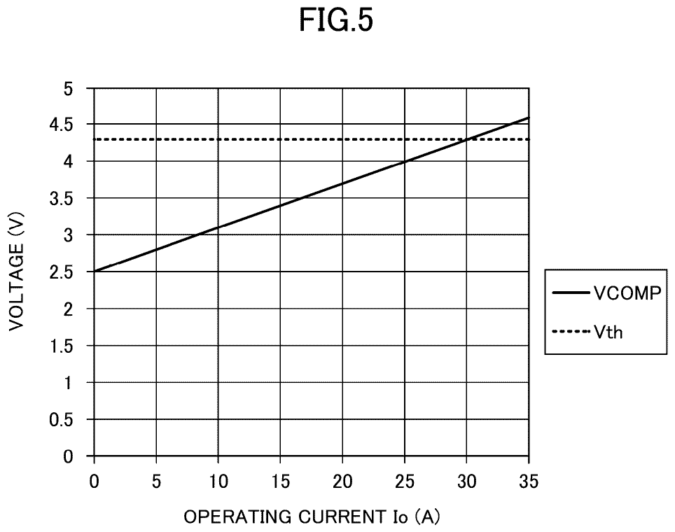

FIG. 4 is a characteristic diagram illustrating an example of a relationship between the operating current Io and amplified output voltages VOUTM and VOUTP. The first amplified output voltage VOUTM is the voltage of the first amplification output terminal 16, and is equal to the first output voltage Vout− of the first output terminal VOUT−. The second amplified output voltage VOUTP is the voltage of the second amplification output terminal 17, and is equal to the second output voltage Vout+ of the second output terminal VOUT+. The analog differential voltage Vsa corresponds to a difference (=VOUTP−VOUTM) between the first amplified output voltage VOUTM and the second amplified output voltage VOUTP. FIG. 4 illustrates a case where the common mode setting voltage Vocm is set to 2.5 volts (V).

In FIG. 2, the analog differential voltage Vsa is input to a difference input portion of the ADC 61. By employing the ADC 61 of the differential input type, it is possible to reduce an analog-to-digital conversion error caused by common mode noise. The gain of the amplifier circuit 70 is preferably set to a value that enables the use of the ADC 61 in a full scale range thereof. The amplifier circuit 70 and the ADC 61 detect the operating current Io, and the current limiting function is achieved to limit the variation in the operating current Io through the ADC 61, so that the operating current Io exceeding the current limit value does not flow.

For example, the limit value db described above, corresponding to the current limit value, may be an upper limit value or a lower limit value of the full scale range of the ADC 61. In FIG. 4, in a case where the full scale range of the ADC 61 is from the lower limit value of 0.5 V to the upper limit value of 4.5 V, the operating current Io is limited so as not to fall below −16 amperes (A) or so as not to rise above +16 A. When the operating current Io becomes lower than −16 A or higher than +16 A, the digital value d output from the ADC 61 becomes saturated. When the digital value d becomes saturated, the digital value d is maintained at a constant value, and thus, the controller 60 outputs the pulse width modulation signal Sc at a constant duty ratio. Accordingly, it is possible to achieve the current limiting function which limits the value of the operating current Io to the current limit value of −16 A or +16 A.

For example, the limit value db described above, corresponding to the current limit value, may be a set upper limit value that is set to a value lower than the upper limit value of the full scale range of ADC 61 or a set lower limit value that is set to a value higher than the lower limit value of the full scale range of ADC 61. The set upper limit value and the set lower limit value are values set in the controller 60. When the digital value d output from the ADC 61 increases and reaches the set upper limit value, or when the digital value d output from the ADC 61 decreases and reaches the set lower limit value, the controller 60 stops varying the duty ratio of the pulse width modulation signal Sc. In a state where the digital value d reached the set upper limit value or the set lower limit value, the controller 60 outputs the pulse width modulation signal Sc so that the duty ratio becomes constant. Thus, it is possible to achieve the current limiting function which limits the value of the operating current Io by the current limit value.

In FIG. 2, when the overcurrent detection circuit 80 detects the sense voltage Vs exceeding the predetermined voltage Va, the overcurrent detection circuit 80 asserts the detection signal OC. The overcurrent detection circuit 80 includes a differential input single end output circuit 83, and a comparator circuit 84.

The differential input single end output circuit 83 amplifies and converts the sense voltage Vs into a single end signal VCOMP. A voltage value of the single end signal VCOMP represents the magnitude of the operating current Io. The differential input single end output circuit 83 includes a single end output amplifier 81, and a plurality of resistors R41, R51, R42, and R52. The single end output amplifier 81 converts the sense voltage Vs into the single end signal VCOMP. The single end output amplifier 81 has a first input terminal VIN−, a second input terminal VIN+, and an output terminal VOUT.

The resistor R41 is connected between the first sense terminal 13 and the first input terminal VIN−. The resistor R42 is connected between the second sense terminal 14 and the second input terminal VIN+. The resistor R51 is connected between the output terminal VOUT and the first input terminal VIN−. The resistor R52 is connected between the buffer 79 of the setting circuit 76 and the second input terminal VIN+. The output terminal VOUT is connected to a comparator 82 of the comparator circuit 84.

Device constants, such as the resistance values of the plurality of resistors R41, R51, R42, and R52 or the like, are set so that a gain of the differential input single end output circuit 83 is smaller than the gain of the amplifier circuit 70. In this case, it is possible to prevent the voltage value of the single end signal VCOMP from staying near a value of the power supply voltage of the single end output amplifier 81 before the overcurrent protection function is activated. If the gains of the differential input single end output circuit 83 and the amplifier circuit 70 are the same, the voltage value of the single end signal VCOMP may stay near the value of the power supply voltage of the single end output amplifier 81 before the overcurrent protection function is activated.

The buffer 79 of the setting circuit 76 is connected to the second input terminal VIN+ of the single end output amplifier 81, via the resistor R52. Thus, the sense voltage Vs input to the single end output amplifier 81 is offset by the common mode setting voltage Vocm generated by the setting circuit 76. Accordingly, the overcurrent detection circuit 80 shares the common mode setting voltage Vocm generated by the setting circuit 76 with the amplifier circuit 70, thereby enabling the scale of the drive circuit 101 to be reduced, and the scale of the semiconductor integrated circuit 500 to be reduced.

The comparator circuit 84 includes the comparator 82 that compares the single end signal VCOMP with a predetermined threshold voltage Vth, and outputs the detection signal OC according to a comparison result. In this example, the threshold value voltage Vth is generated by dividing the power supply voltage VDD50 by the resistors R6 and R7 forming a resistance voltage divider. When the comparator 82 detects the single end signal VCOMP higher than the threshold voltage Vth, the comparator 82 asserts the detection signal OC.

FIG. 5 is a characteristic diagram illustrating an example of a relationship of the operating current Io, the single end signal VCOMP, and the threshold voltage Vth. FIG. 5 illustrates a case where the common mode setting voltage Vocm is set to 2.5 V. Because the sense voltage Vs is offset by the common mode setting voltage Vocm, the single end signal VCOMP is also offset by the same voltage as the common mode setting voltage Vocm. The threshold voltage Vth may be set so that the value of the operating current Io at which the overcurrent protection function is activated is higher than the current limit value described above.

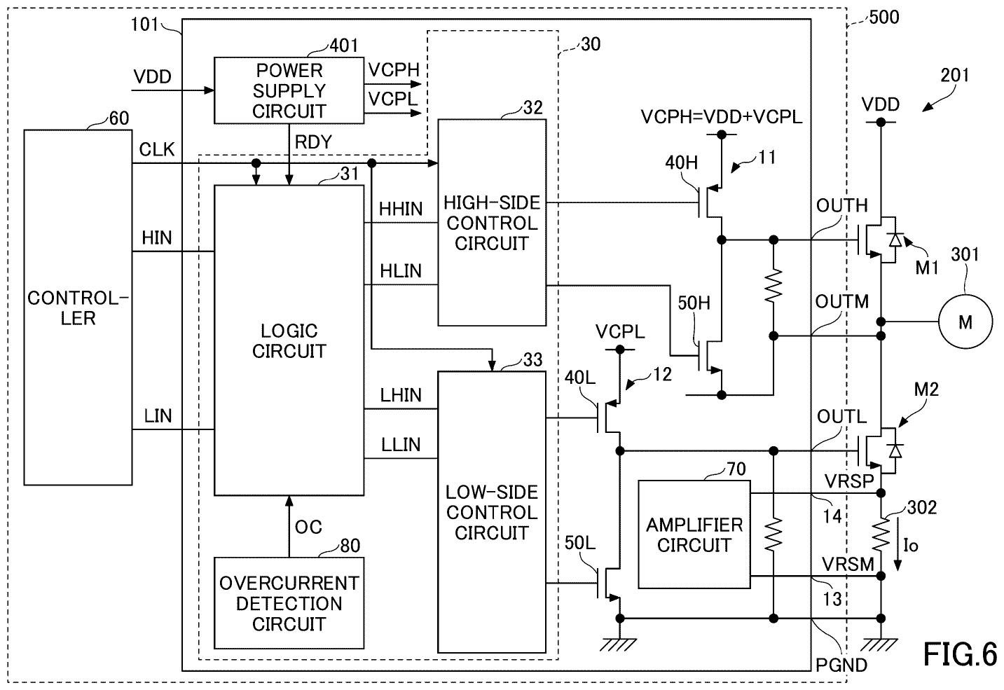

FIG. 6 is a diagram illustrating an example of a configuration of a power conversion device including the semiconductor integrated circuit according to one embodiment. A power conversion circuit 201, which forms the power conversion device, converts a DC voltage VDD supplied from a DC power supply into an AC voltage to be supplied to a load 301, such as a motor M or the like. The power conversion circuit 201 includes a high-side transistor M1, a low-side transistor M2, and a drive circuit 101 configured to drive the transistors M1 and M2. The drive circuit 101 is built into the semiconductor integrated circuit 500.

In a case where the power conversion circuit 201 is an inverter configured to generate a three-phase AC power of phases U, V, and W, for example, the power conversion circuit 201 includes three switching circuits having the same configuration including the transistors M1 and M2 and the drive circuit 101, respectively. FIG. 6 illustrates one switching circuit of a plurality of switching circuits (for example, three switching circuits of the phases U, V, and W) included in the power conversion circuit 201.

The power conversion circuit 201 is not limited to an inverter configured to convert the direct current into the alternating current, and may be a converter configured to convert the direct current into a direct current. The power conversion circuit 201 may be used as a power supply circuit. In this example, the load 301 is the motor M that rotates a cooling fan or the like, but the type of the load 301 is not limited thereto.

The drive circuit 101 is configured to drive the transistors M1 and M2 that are externally connected to the drive circuit 101. Each of the transistors M1 and M2 is a gate-driven switching element having a first main electrode, a second main electrode, and a gate electrode. Specific examples of the gate-driven switching element include an N-channel field effect transistor (FET) having a drain, a source, and a gate, an insulated gate bipolar transistor (IGBT) having a collector, an emitter, and a gate, or the like. Specific examples of the FET include a metal oxide semiconductor field effect transistor (MOSFET) or the like. The drain or the collector is an example of the first main electrode. The source or the emitter is an example of the second main electrode. FIG. 6 illustrates a case where the transistors M1 and M2 are N-channel FETs.

The drive circuit 101 is a pre-driver configured to drive the transistors M1 and M2 that drive the load 301, such as the motor M or the like. The drive circuit 101 is formed by an integrated circuit, for example.

The drive circuit 101 is configured to drive the transistors M1 and M2 according to signals (a clock CLK, a high-side command signal HIN, and a low-side command signal LIN) supplied from the controller 60, so as to switch (that is, turn on or off) the transistors M1 and M2. The high-side command signal HIN and the low-side command signal LIN vary in synchronism with the clock CLK. The high-side command signal HIN includes an ON command for commanding the high-side transistor M1 to be turned on, and an OFF command for commanding the high-side transistor M1 to be turned off. The low-side command signal LIN includes an ON command for instructing the low-side transistor M2 to be turned on, and an OFF command for instructing the low-side transistor M2 to be turned off. The drive circuit 101 alternately turns on the transistors M1 and M2, with a dead time for turning off the transistors M1 and M2 interposed therebetween, according to the high-side command signal HIN and the low-side command signal LIN.

The drive circuit 101 includes a control circuit 30, a high-side source current source 40H, a high-side sink current source 50H, a low-side source current source 40L, and a low-side sink current source 50L. In addition, the drive circuit 101 includes a high-side drive terminal OUTH, an intermediate terminal OUTM, a low-side drive terminal OUTL, and a ground terminal PGND. The drive circuit 101 further includes a power supply circuit 401.

The control circuit 30 is configured to control the source current source 40H that turns on the transistor M1, and to control the sink current source 50H that turns off the transistor M1. Moreover, the control circuit 30 is configured to control the source current source 40L that turns on the transistor M2, and to control the sink current source 50L that turns off the transistor M2. The control circuit 30 includes a logic circuit 31, a high-side control circuit 32, and a low-side control circuit 33.

The logic circuit 31 is configured to generate a drive command HHIN for source control and a drive command HLIN for sink control, based on the high-side command signal HIN and the low-side command signal LIN. In addition, the logic circuit 31 is configured to generate a drive command LHIN for source control and a drive command LLIN for sink control, based on the high-side command signal HIN and the low-side command signal LIN. The logic circuit 31 may be provided externally to the control circuit 30 or the drive circuit 101. The drive command HHIN is an example of a source drive command. The drive command HLIN is an example of a sink drive command.

The high-side control circuit 32 is configured to control a source current generated by the high-side source current source 40H, according to the drive command HHIN for source control. In addition, the high-side control circuit 32 is configured to control a sink current generated by the high-side sink current source 50H, according to the drive command HLIN for sink control. The high-side control circuit 32 is configured to alternately turn on output transistors of the current sources 40H and 50H, with a dead time for turning off the output transistors of the current sources 40H and 50H interposed therebetween, according to the drive command HHIN and the drive command HLIN.

The low-side control circuit 33 is configured to control a source current generated by the low-side source current source 40L, according to the drive command LHIN for source control. In addition, the low-side control circuit 33 is configured to control a sink current generated by the low-side sink current source 50L, according to the drive command LLIN for sink control. The low-side control circuit 33 is configured to alternately turn on output transistors of the current sources 40L and 50L, with a dead time for turning off the output transistors of the current sources 40L and 50L interposed therebetween, according to the drive command LHIN and the drive command LLIN.

The source current source 40H includes the output transistor formed of a P-channel MOSFET, and generates a source current to be delivered to a gate of the transistor M1. The source current source 40H is connected between the drive terminal OUTH connected to the gate of the transistor M1, and a power supply node of a high-side power supply voltage VCPH.

The power supply voltage VCPH is equal to a sum of the DC voltage VDD and a low-side power supply voltage VCPL. The power supply voltage VCPH is generated by a charge pump inside the power supply circuit 401, using the DC voltage VDD and the power supply voltage VCPL, for example.

The sink current source 50H includes the output transistor formed by an N-channel MOSFET, and generates a sink current to be absorbed from the gate of the transistor M1. The sink current source 50H is connected between the drive terminal OUTH connected to the gate of the transistor M1, and the intermediate terminal OUTM connected to the load 301.

The source current source 40L includes the transistor formed of a P-channel MOSFET, and generates a source current to be delivered to the gate of the transistor M2. The source current source 40L is connected between the drive terminal OUTL connected to the gate of the transistor M2, and a power supply node of the low-side power supply voltage VCPL.

The sink current source 50L includes the output transistor formed by an N-channel type MOSFET, and generates a sink current to be absorbed from the gate of the transistor M2. The sink current source 50L is connected between the drive terminal OUTL connected to the gate of the transistor M2, and the ground terminal PGND connected to the ground.

The drive circuit 101 is configured to drive the transistors M1 and M2 by a constant current driving method. The drive circuit 101 delivers the source current from the PMOS output transistor of the source current source 40H to the drive terminal OUTH, so as to charge the gate of the transistor M1 and turn on the transistor M1. The drive circuit 101 absorbs the sink current from the drive terminal OUTH into the NMOS output transistor of the sink current source 50H, so as to discharge the gate of the transistor M1 and turn off the transistor M1. Similarly, the drive circuit 101 delivers the source current from the PMOS output transistor of the source current source 40L to the drive terminal OUTL, so as to charge the gate of the transistor M2 and turn on the transistor M2. The drive circuit 101 absorbs the sink current from the drive terminal OUTL into the NMOS output transistor of the sink current source 50L, so as to discharge the gate of the transistor M2 and turn off the transistor M2.

The drive circuit 101 includes the high-side source current source 40H, as the first current source 11 that uses a step-up (or boost) voltage (power supply voltage VCPH) generated by a charge pump inside the power supply circuit 401. The drive circuit 101 includes the low-side source current source 40L, as the second current source 12 that uses a step-down (or buck) voltage (power supply voltage VCPL) generated by a regulator inside the power supply circuit 401. The charge pump generates the power supply voltage VCPH as a power supply voltage for operating the source current source 40H that delivers the source current to the drive terminal OUTH. The power supply circuit 401 includes a voltage monitoring circuit configured to monitor the power supply voltage VCPH and to assert an output signal RDY when a detected value of the power supply voltage VCPH rises above a threshold value.

When the output signal RDY generated by the voltage monitoring circuit inside the power supply circuit 401 is asserted, the logic circuit 31 enables the operations of the high-side source current source 40H and the low-side source current source 40L. Accordingly, the logic circuit 31 starts generating the drive command HHIN for source control and the drive command HLIN for sink control, based on the high-side command signal HIN and the low-side command signal LIN. The logic circuit 31 starts generating the drive command LHIN for source control and the drive command LLIN for sink control, based on the high-side command signal HIN and the low-side command signal LIN. Accordingly, when the output signal RDY is asserted, the first current source 11 and the second current source 12 can prevent the driving targets (the transistors M1 and M2 and the load 301) from being driven in a state where the power supply voltage VCPH generated by the step-up operation of the charge pump 90 has not increased sufficiently.

The transistors M1 and M2 and the load 301 are examples of the driving target 300 illustrated in FIG. 1, and the first current source 11 or the second current source 12 is an example of the current source 10 illustrated in FIG. 1. The first current source 11 includes the source current source 40H configured to generate the source current to be supplied to the drive terminal OUTH, and the sink current source 50H configured to generate the sink current to be supplied to the drive terminal OUTH. The second current source 12 includes the source current source 40L configured to generate the source current to be supplied to the drive terminal OUTL, and the sink current source 50L configured to generate the sink current to be supplied to the drive terminal OUTL. The source current supplied to the drive terminal OUTH, or the source current supplied to the drive terminal OUTL, is an example of the drive current Id supplied to the drive terminal 15 illustrated in FIG. 1.

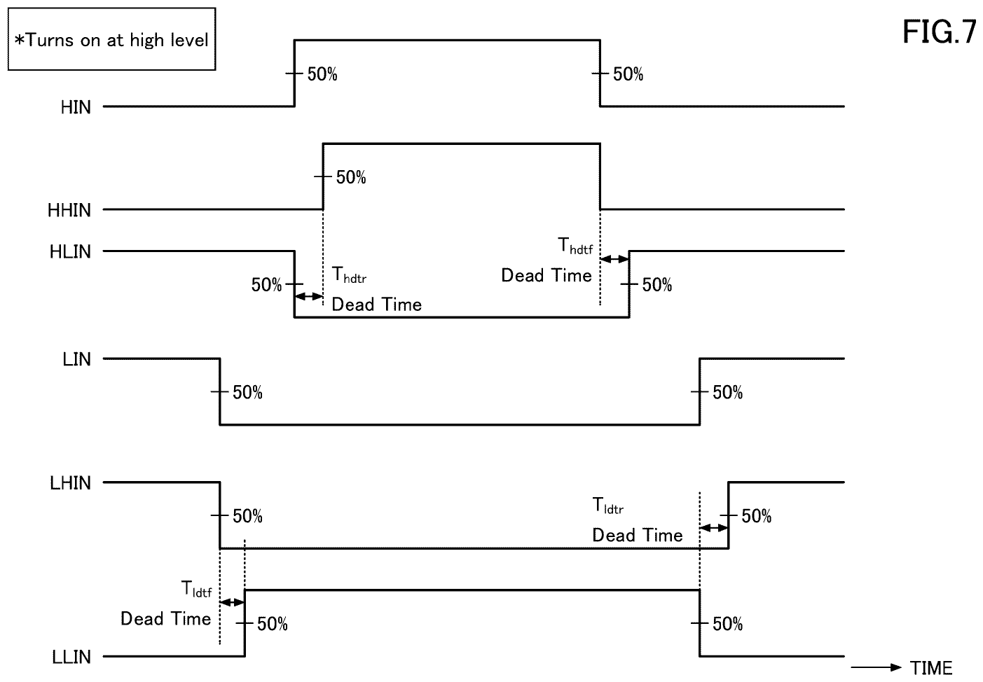

FIG. 7 is a diagram illustrating an example of the pulse width modulation signal and a driving pattern. In FIG. 7, the high-side command signal HIN and the low-side command signal LIN correspond to the pulse width modulation signal Sc generated by the controller 60 illustrated in FIG. 1. In FIG. 7, the drive command HHIN for source control, the drive command HLIN for sink control, the drive command LHIN for source control, and the drive command LLIN for sink control, correspond to the drive pattern DP generated by the logic circuit 31 illustrated in FIG. 1. As illustrated in FIG. 7, the logic circuit 31 generates the drive pattern DP (the drive command HHIN, the drive command HLIN, the drive command LHIN, and the drive command LLIN) according to the pulse width modulation signal Sc (the high-side command signal HIN and the low-side command signal LIN).

For example, the controller 60 increases an on-duty ratio of the high-side command signal HIN as the digital value d output from the ADC 61 increases, while maintaining an on-duty ratio of the low-side command signal LIN in a constant state. When the digital value d reaches the limit value db (upper limit value), the controller 60 stops increasing the on-duty ratio of the high-side command signal HIN. Thus, the increase in the operating current Io is limited by the current limit value (current upper limit value). Similarly, the controller 60 decreases the on-duty ratio of the high-side command signal HIN as the digital value d output from the ADC 61 decreases, while maintaining the on-duty ratio of the low-side command signal LIN in a constant state. When the digital value d reaches the limit value db (lower limit value), the controller 60 stops decreasing the on-duty ratio of the high-side command signal HIN. Hence, the decrease in the operating current Io is limited by the current limit value (current lower limit value).

According to each of the embodiments, it is possible to provide a semiconductor integrated circuit having the current limiting function and the overcurrent protection function.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor integrated circuit comprising:
a drive terminal;
a first sense terminal;
a second sense terminal;
a current source configured to generate a drive current to be supplied to the drive terminal;
an amplifier circuit configured to differentially amplify a sense voltage between the first sense terminal and the second sense terminal, and output an analog differential voltage;
an analog-to-digital converter configured to convert the analog differential voltage output from the amplifier circuit into a digital value;
a command circuit configured to generate a command signal based on the digital value, so that the sense voltage does not deviate outside a predetermined range;
an overcurrent detection circuit configured to assert a detection signal when the sense voltage exceeds a predetermined voltage; and
a logic circuit configured to generate a drive pattern for causing the current source to generate the drive current according to the command signal, and stop the supply of the drive current when the detection signal is asserted.

2. The semiconductor integrated circuit as claimed in claim 1, further comprising:
a setting circuit configured to generates a common mode setting voltage,
wherein the amplifier circuit includes a differential amplifier configured to control a common mode voltage, which is an average of a first output voltage and a second output voltage forming the analog differential voltage, to the common mode setting voltage generated by the setting circuit.

3. The semiconductor integrated circuit as claimed in claim 2, wherein the overcurrent detection circuit shares the common mode setting voltage generated by the setting circuit with the amplifier circuit.

4. The semiconductor integrated circuit as claimed in claim 3, wherein
the overcurrent detection circuit includes a single end output amplifier configured to convert the sense voltage into a single end signal, and
the sense voltage input to the single end output amplifier is offset by the common mode setting voltage generated by the setting circuit.

5. The semiconductor integrated circuit as claimed in claim 4, wherein the overcurrent detection circuit includes a comparator configured to compare the single end signal with a predetermined threshold voltage, and assert the detection signal.

6. A semiconductor integrated circuit comprising:
a drive terminal;
a first sense terminal;
a second sense terminal;
a current source configured to generate a drive current to be supplied to the drive terminal;
an amplifier circuit configured to differentially amplify a sense voltage between the first sense terminal and the second sense terminal, and output an analog differential voltage;
an analog-to-digital converter configured to convert the analog differential voltage output from the amplifier circuit into a digital value;
a command circuit configured to vary a command signal according to a variation in the digital value, and stop varying the command signal when the digital value reaches a limit value;
an overcurrent detection circuit configured to assert a detection signal when the sense voltage exceeds a predetermined voltage; and
a logic circuit configured to generate a drive pattern for causing the current source to generate the drive current according to the command signal, and stop the supply of the drive current when the detection signal is asserted.

7. The semiconductor integrated circuit as claimed in claim 6, further comprising:
a setting circuit configured to generates a common mode setting voltage,
wherein the amplifier circuit includes a differential amplifier configured to control a common mode voltage, which is an average of a first output voltage and a second output voltage forming the analog differential voltage, to the common mode setting voltage generated by the setting circuit.

8. The semiconductor integrated circuit as claimed in claim 7, wherein the overcurrent detection circuit shares the common mode setting voltage generated by the setting circuit with the amplifier circuit.

9. The semiconductor integrated circuit as claimed in claim 8, wherein
the overcurrent detection circuit includes a single end output amplifier configured to convert the sense voltage into a single end signal, and
the sense voltage input to the single end output amplifier is offset by the common mode setting voltage generated by the setting circuit.

10. The semiconductor integrated circuit as claimed in claim 9, wherein the overcurrent detection circuit includes a comparator configured to compare the single end signal with a predetermined threshold voltage, and assert the detection signal.
